(19) United States
(12) Patent Application Publication
(10) Pub. No.: US 2008/0169479 A1
(43) Pub. Date: Jul. 17, 2008

(54) LIGHT-EMITTING DIODE

(75) Inventors: ZHEN-FENG XU, Beijing (CN); GUO-FAN JIN, Beijing (CN); SHOU-SHAN FAN, Beijing (CN)

Correspondence Address: PCE INDUSTRY, INC.;ATT. CHENG-JU CHIANG, 458 E. LAMBERT ROAD, FULLERTON, CA, 92835, US

(73) Assignees: TSINGHUA UNIVERSITY, Beijing (CN); HON HAI PRECISION INDUSTRY CO., LTD., Tu-Cheng (TW)

(21) Appl. No.: 11/938,467

(22) Filed: Nov. 12, 2007

(30) Foreign Application Priority Data
Jan. 12, 2007 (CN) 200710072946.9

(51) Int. Cl. H01L 33/00

(52) U.S. Cl. 257/94; 257/E33.001

(57) ABSTRACT

A light-emitting diode includes a substrate (110), a reflective layer (120), a second diffraction grating (130), a first semiconductor layer (142), an active layer (144), a second semiconductor layer (146), a transparent electrode layer (148), and a first diffraction grating (150), arranged in that order. The first diffraction grating and the second diffraction grating is composed of an array of parallel and equidistant grooves, and a inclined angle between the grooves of the first diffraction grating and the grooves of the second diffraction grating is equal to or more than 0° and equal to or less than 90°. One of the first semiconductor layer and the second semiconductor layer is an N-type semiconductor and the other thereof is a P-type semiconductor. The light-emitting diode has high light extraction efficiency and is easy to manufacture at a low cost.

### BACKGROUND

1. Field of the Invention

The present invention relates to light-emitting devices and, particularly, to a light-emitting diode (LED).

2. Discussion of Related Art

LEDs are semiconductors that convert electrical energy into light. Compared to conventional light sources, the LEDs have higher energy conversion efficiency, higher radiance (i.e., they emit a larger quantity of light per unit area), longer lifetime, higher response speed, and better reliability. At the same time, LEDs generate less heat. Therefore, LED modules are widely used in particular as a semiconductor light source in conjunction with imaging optical systems, such as displays, projectors, and so on.

A conventional LED includes a substrate, a first electrode layer formed on the substrate, an N-type semiconductor layer, an active layer, a P-type semiconductor layer and a second electrode layer typically disposed in stack. In operation, a voltage is applied between the first electrode layer and the second electrode layer, electrons are injected from the N-type semiconductor layer into the active layer and holes are injected from the P-type semiconductor layer into the active layer. The electrons and holes release energy in the form of photons as they recombine in the active layer.

However, most of the light rays emitted within an LED are lost due to total internal reflection at the LED-air interface. Typical semiconductor materials have a higher refraction index than the air, and thus, according to Snell's law, most of the light rays will be remained in LED, and eventually dissipates therein, thereby degrading efficiency. Therefore, the conventional LED has low extraction efficiency, and then has low brightness.

One method for reducing the effects of the total internal reflection is to form one-dimension grating on the second electrode layer. The one-dimension grating is comprised of an array of grooves. The grooves are parallel to one another and equidistant therebetween. The one-dimension grating destroys the total internal reflection of light rays in a plane perpendicular to the grooves of the one-dimension grating, and thus the extraction efficiency of LED is improved. However, the light rays in a plane parallel to the grooves of the one-dimension grating are still reflected on the LED-air interface by the total internal reflection. The extraction efficiency of the LED is less than 25%.

Therefore, an LED that has high extraction efficiency and is easy to manufacture at low cost is desired.

### SUMMARY OF THE INVENTION

A light-emitting diode includes a substrate, a reflective layer, a second diffraction grating, a second type semiconductor layer, an active layer, a first typer semiconductor layer, a transparent electrode layer and a first diffraction grating arranged in the order. The first diffraction grating and the second diffraction grating is composed of an array of parallel and equidistant grooves, and a inclined angle between the grooves of the first diffraction grating and the grooves of the second diffraction grating is equal to or more than 0° and equal to or less than 90°.

Compared with a conventional LED, the present LED has high extraction efficiency, e.g., up to about 50% with a simple configure, that is, a second diffraction grating. The periods of the diffraction grating are comparable with the wavelength of light rays emitted from the LED, and thus the LED can be manufracted by a conventional etch technology. Therefore, the present LED is easy to manufract at low lost.

### BRIEF DESCRIPTION OF THE DRAWINGS

Many aspects of the present LED can be better understood with reference to the following drawings. The components in the drawings are not necessarily to scale, the emphasis instead being placed upon clearly illustrating the present LED.

FIG. 1 is a schematic, solid view of an LED according to a first embodiment;

FIG. 2 is a cross-sectional side view of an LED according to a first embodiment; and

FIG. 3 is a schematic, solid view of an LED according to a second embodiment.

### DETAILED DESCRIPTION OF PREFERRED EMBODIMENTS

The present LED is further described below with reference to the drawings.

The present LED includes a substrate, a reflective layer, an N-type semiconductor layer, an active layer, a P-type semiconductor layer and a transparent electrode layer typically disposed in stack. Furthermore, the present LED includes a first diffraction grating formed on the transparent electrode layer, and a second diffraction grating between the reflective layer and the N-type semiconductor. The reflective layer functions as a mirror and an electrode, and the reflective layer can be disposed on the substrate or/and directly on the second diffraction grating. The first diffraction grating and the second diffraction grating include an array of parallel grooves. The grooves belong to the same array are equidistant therebetween. A included angle between the grooves of the first diffraction grating and the grooves of the second diffraction grating is in an approximate range of 0° to 90°. With this configure, the total internal reflection in the LED is reduced. By choosing suitable gemetry of the first diffraction grating and the second diffractin grating, a high extraction efficiency can be achieved, such as up to 50%.

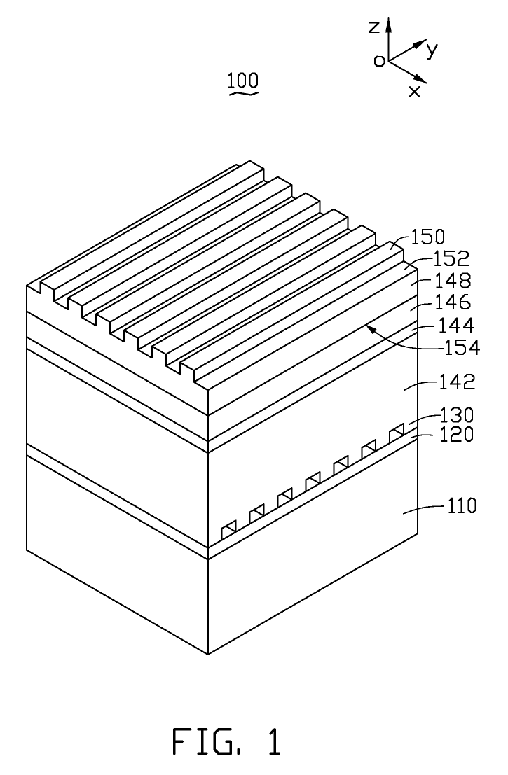

Referring to FIG. 1, an LED 100, according to the first embodiment, is shown. The LED 100 includes a substrate 110, a reflective layer 120, an N-type semiconductor layer 142, an active layer 144, a P-type semiconductor layer 146, a transparent electrode layer 148, a first diffraction grating 150 and a second diffraction grating 130. The substrate 110, the reflective layer 120, the second diffraction grating 130, the N-type semiconductor layer 142, the active layer, the P-type semiconductor layer 146, the transparent electrode and the first diffraction grating are arranged in the order, i.e., typically disposed in stack.

The reflective layer 120 is deposited on the substrate 110, or selectively, on the surface of the second diffraction grating 130. The reflective layer 120 functions as a mirror and an electrode. The transparent electrode layer 148 includes a top surface 152 and a bottom surface 154. The bottom surface 154 is connected with the P-type semiconductor layer 146, and the top surface 152 is connected with or attached to the first diffraction grating 150. The first diffraction grating 150 and the second diffraction grating 130 include an array of parallel and equidistant grooves. The first diffraction grating 150 is a one-dimension grating-structure etched/formed in the top surface 152, or an optical film with a one-dimension grating-structure attached on the top surface 152. The second diffraction grating 130 is a one-dimension grating-structure etched in/formed in the surface of the N-type semiconductor layer 142, or an optical film with a one-dimension grating-structure attached on the surface of the N-type semiconductor layer 142. The periods of the first diffraction grating 150 and the second diffraction grating 130 are comparable to the wavelength of light rays. The grooves of the first diffraction grating 150 are perpendicular to the grooves of second diffraction grating 130.

The N-type semiconductor layer 142 is made of a material selected from the group consisting of N-type gallium nitride (n-GaN), N-type gallium arsenide (n-GaAs), and N-type copper phosphide (n-CuP). The P-type semiconductor layer 146 is made of a transparent material selected from the group consisting of P-type gallium nitride (P-GaN), P-type gallium arsenide (P-GaAs), and P-type copper phosphide (P-CuP). The substrate 110 can be made of a material, such as sapphire, GaAs, InP, Si, SiC or SiN. The reflective layer 120 is a metal layer, such as silver or aluminum. The transparent electrode layer 148 may be an ITO layer.

In operation, electrons are injected from the N-type semiconductor layer 142 into the active layer 144, and holes are injected from the P-type semiconductor layer 146 into the active layer 144. The electrons and holes recombine in the active layer 144, release energy in the form of photons and emit light rays. The wavelength of the light rays, and therefore theirs color, depends on the bandgap energy of the materials of the N-type semiconductor layer 142 and the P-type semiconductor layer 146. In the present embodiment, The N-type semiconductor layer 142 is made of n-GaAs, the P-type semiconductor layer 146 is made of P-GaAs, and the active layer 144 is made of indium gallium nitride (InGaN). Thus, the light rays emitting from the active layer 144 have a wavelength of about 455 nanometers (nm).

The light rays transport through the P-type semiconductor layer 146, and arrive at the interface between the P-type semiconductor layer 146 and the transparent electrode layer 148. A refractive index of the P-type semiconductor 146 is n1, and a refractive index of the transparent electrode layer 148 is n2, according to Snell's law: sin θc1=n2/n1, a critical angle is θc1. The critical angle θc1 is an inclined angle between the light rays and a normal line perpendicular to the bottom surface 154. Therefore, only the light rays with an angle equal to or less than θc1 will be refracted into the transparent electrode layer 148. Thereafter, the light rays arrive at the top surface 152. A refractive index of the air is n3, according to Snell's law: sin θc2=n3/n2, a critical angle is θc2. The critical angle θc2 is an inclined angle between the light rays and a normal line perpendicular to the top surface 152. Only the light rays with an angle equal to or less than θc2 will be refracted through the top surface 152 into the air, i.e., will be extracted out of the LED 100. The refractive index n2 is larger than the refractive index n3, and thus the critical angle θc1 is smaller than the critical angle θc2. The light rays equal to or less than θc1 will be refracted through the bottom surface 154 and the top surface 152, and will be extracted out of the LED 100. In the present embodiment, the air has a refractive index of n3=1, the P-type semiconductor layer 146 has a refractive index of n1=2.45, and then the critical angle is about 24°.

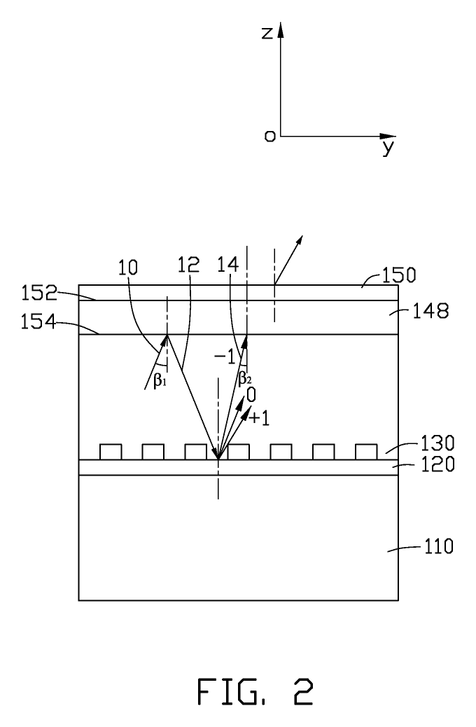

In the present embodiment, there is a first diffraction grating 150 is formed on the transparent electrode layer 148. Therefore, the light rays in a plane perpendicular to the grooves of the first diffraction grating 150 will be refracted out, because the period thereof is comparable to the wavelength of the light rays. In the other side, referring to FIG. 2, the light rays in a plane parallel to the grooves of the first diffraction grating 150 will experience the total internal reflection. That is, the light rays with an angle to a normal line equal to or less than 24° will be refracted out of the LED 100, and the light rays 10 with an angle β1 to the normal line more than 24° will be reflected back into the LED as the light rays 12. The light rays 12 arrive at the second diffraction grating 130 and then are diffracted thereby, because the light rays 12 is in the plane perpendicular to the grooves of the second diffraction grating 130, and the wavelength of light rays 12 is comparable to the period of the second diffraction grating 130. Moreover, the light rays 120 will experience the coactions of the second diffraction grating 130 and the reflective layer 120, and then are changed into the light rays 14 transporting toward the transport electrode layer 148. The light rays 14 arrive at the bottom surface 154, wherein one portion of the light rays 14 with an angle β2 to the normal line equal to or less than 24° will be extracted or refracted out of the LED 100, and the other portion of the light rays 14 with an angle to the normal line more than 24° will be reflected back to the LED again.

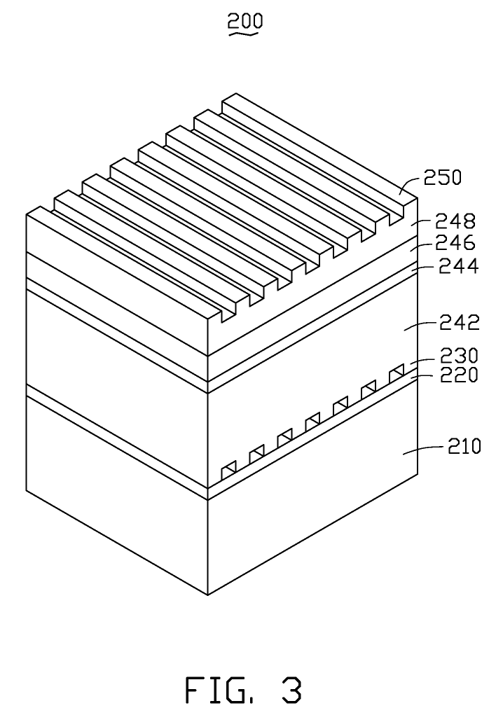

Additionally, the light rays in a plane that is closely perpendicular to the grooves of the first diffraction grating 150 will incline to be extracted out of the LED 100 directly, and the light rays in a plane that is closely parallel to the grooves of the first diffraction grating 150 will incline to act as the light rays shown in FIG. 3.

In the LED 100, a width of ITO is about 300-400 nm. A period of the first diffraction grating 150 is about 500-700 nm, a duty cycle thereof is about 0.3-0.7, and a depth of the groove thereof is about 100-200 nm. A period of the second diffraction grating 130 is about 400-500 nm, a duty cycle thereof is about 0.3-0.7, and a depth of the groove thereof is about 70-150 nm. Accordingly, a light extraction efficiency of the LED 100 is about 48.6%.

Referring to FIG. 3, an LED 200 according to the second embodiment is shown. The LED 200 includes a substrate 210, a reflective layer 220, a second diffraction grating 230, an N-type semiconductor layer 242, an active layer 244, a P-type semiconductor layer 246, a transparent electrode layer 248 and a first diffraction grating 250 typically disposed in stack. The LED 200 is similar to the LED 100, except that the grooves of the first diffraction grating 250 are parallel to that of the second diffraction grating 230. The light extraction efficiency of the LED 200 is about 28.6%, higher than that of the conventional LED with only the first diffraction grating.

It is known to the one killed in the field than the LED also can include a substrate, a reflective layer, a second diffraction grating, a P-type semiconductor layer, an active layer, an N-type semiconductor layer, a transparent electrode layer and a first diffraction grating disposed in stack. Further, the substrate can be removed, and the reflective layer is directly formed on the second diffraction grating. Alternatively, a number of reflective layers are formed on the other sides of the LED, in order to enhance the light extraction efficiency.

Finally, it is to be understood that the embodiments mentioned above are intended to illustrate rather than limit the invention. Variations may be made to the embodiments without departing from the spirit of the invention as claimed. The above-described embodiments illustrate the scope of the invention but do not restrict the scope of the invention.

What is claimed is:

1. A light-emitting diode comprising:
a substrate, a reflective layer, a second diffraction grating, a first semiconductor layer, an active layer, a second semiconductor layer, a transparent electrode layer and a first diffraction grating arranged in the order, wherein the first diffraction grating and the second diffraction grating is composed of an array of parallel and equidistant grooves, and a inclined angle between the grooves of the first diffraction grating and the grooves of the second diffraction grating is equal to or more than 0° and equal to or less than 90°, and further wherein one of the first semiconductor layer and the second semiconductor layer is an N-type semiconductor and the other thereof is a P-type semiconductor.

2. The light-emitting diode as claimed in claim 1, wherein the second semiconductor layer is an N-type semiconductor layer, and the first semiconductor layer is a P-type semiconductor layer.

3. The light-emitting diode as claimed in claim 1, wherein the second semiconductor layer is a P-type semiconductor layer, and the first semiconductor layer is an N-type semiconductor layer.

4. The light-emitting diode as claimed in claim 1, wherein the reflective layer is disposed at least one of on the substrate and on a surface of the second semiconductor layer.

5. The light-emitting diode as claimed in claim 1, wherein a duty cycle of the first diffraction grating is about 0.3-0.7, and a depth of the grooves of the first diffraction grating is about 100-200 nm.

6. The light-emitting diode as claimed in claim 1, wherein a duty cycle of the second diffraction grating is about 0.3-0.7, and a depth of the grooves of the second diffraction grating is about 70-150 nm.

7. The light-emitting diode as claimed in claim 1, wherein the first diffraction grating and the second diffraction grating are transmission gratings.

8. The light-emitting diode as claimed in claim 1, wherein the periods of the first diffraction grating and the second diffraction grating are chosen so as to be approximately the same as the wavelength of light rays emitted from the light-emitting diode.

9. The light-emitting diode as claimed in claim 8, wherein the period of the first diffraction grating is about 500-700 nm.

10. The light-emitting diode as claimed in claim 8, wherein the period of the second diffraction grating is about 400-500 nm.

11. The light-emitting diode as claimed in claim 1, wherein the first diffraction grating is one of a grating-structure etched in a surface of the transparent electrode layer and an optical film with a grating-structure attached to the transparent electrode layer.

12. The light-emitting diode as claimed in claim 1, wherein the second diffraction grating is one of a grating-structure etched in a surface of the first semiconductor layer and an optical film with a grating-structure attached to the first semiconductor layer.

13. The light-emitting diode as claimed in claim 1, wherein a width of the transparent electrode layer is about 300-400 nm.

14. The light-emitting diode as claimed in claim 1, wherein the transparent electrode layer comprises a top surface and a bottom surface.

15. The light-emitting diode as claimed in claim 14, wherein the first diffraction grating is attached to the top surface of the transparent electrode layer.

16. The light-emitting diode as claimed in claim 14, wherein the second semiconductor layer is attached to the bottom surface of the transparent electrode layer.
